(19) United States
(12) Patent Application Publication
(10) Pub. No.: US 2025/0023211 A1
(43) Pub. Date: Jan. 16, 2025

(54) CELL WITH INTEGRATED CONDUCTIVE MATERIAL

(71) Applicant: Our Next Energy, Inc., Novi, MI (US)

(72) Inventor: Thomas Patrick Harvey, Novi, MI (US)

(21) Appl. No.: 18/771,806

(22) Filed: Jul. 12, 2024

Related U.S. Application Data
(60) Provisional application No. 63/526,664, filed on Jul. 13, 2023.

(51) Int. Cl. H01M 50/569; G01R 31/3835; G01R 31/396; H01M 10/42; H01M 50/103; H01M 50/119; H01M 50/548; H01M 50/55

(52) U.S. Cl. CPC H01M 50/569; G01R 31/3835; G01R 31/396; H01M 10/425; H01M 50/103; H01M 50/119; H01M 50/548; H01M 50/55; H01M 2010/4271; H01M 2220/20

(57) ABSTRACT

A cell including a housing, a first terminal with a first polarity, a second terminal with a second polarity different from the first polarity, the second terminal being disposed on a second cap plate or on the same first cap plate in a case where the cell has one cap plate. A conductive material is disposed on at least one large wall surface of the cell and dimensioned to cover an area of the cell at the at least one large wall surface. The conductive material further includes a first extension that is electrically coupled to the first terminal, and a second extension that is affixed to the second cap plate or to the same first cap plate.

### BACKGROUND

### Technical Field

The present disclosure generally relates to battery cells and more particularly to a battery cell structure including an integrated conductive material configured for one or more cell management activities.

### Description of the Related Art

Cell arrays configurations typically use an Interconnect Board Assembly (ICB) to enable busbar-based cell-to-cell attachment. During the assembly of the array, a plastic and metal ICB may be welded to the cell terminals. Prior to installation in the array, the busbars may be held in place using the plastic component of the ICB. The busbars then serve as an electrical conduit from the cells to a load.

### BRIEF SUMMARY

According to an embodiment of the present disclosure, a cell is disclosed. The cell includes a housing, a first terminal with a first polarity, the first terminal being disposed on a first cap plate at a first end of the cell and a second terminal with a second polarity different from the first polarity, the second terminal being disposed on a second cap plate at a second end of the cell. The first cap plate and the second cap plate may be the same. The cell further includes a conductive material disposed on at least one large wall surface of the cell and dimensioned to cover or substantially (e.g., more than 80%, or 90% or 98% or 99%) cover a whole area of the cell at the at least one large wall surface. The conductive material further includes a first extension at the first end of the cell that is electrically coupled to the first terminal and a second extension at the second end of the cell that is affixed to the second cap plate. The conductive material may be dimensioned to provide a predetermined resistance for sensing a voltage of the cell.

In one embodiment, a battery pack comprising a plurality of the cells is disclosed. In another embodiment, a method of manufacturing the battery pack or cell including the conductive material for voltage sensing is disclosed.

According to an embodiment of the present disclosure a cell is disclosed including a housing, a first terminal with a first polarity, the first terminal being disposed on a first cap plate and a second terminal with a second polarity different from the first polarity, the second terminal being disposed on a second cap plate or on the same first cap plate and separated by a distance. The cell includes a conductive material comprising a trace pattern with the trace pattern disposed on at least one large wall surface of the cell and the trace pattern configured to optimize a net effective contact area and a uniform heat dissipation of the trace pattern. The trace pattern further includes a first extension that is electrically coupled to the first terminal and a second extension that is affixed to the second cap plate or to the first cap plate when the terminals are on the same cap plate.

In one embodiment, a battery pack comprising a plurality of the cells is disclosed. In another embodiment, a method of manufacturing the battery pack or cell including the trace for balancing or temperature measurement is disclosed.

According to an embodiment of the present disclosure, a cell is disclosed including a housing, a first terminal with a first polarity, a second terminal with a second polarity different from the first polarity, the second terminal being disposed on a second cap plate or on the same first cap plate and separated by a distance. The cell further includes a conductive material that includes a first trace pattern, a second trace pattern and a third trace pattern each including a first extension electrically coupled together at the first terminal and each including a second extension separated from each other on the second cap plate or on the same first cap plate with the terminals being separated by a distance. The first trace pattern may be operable in a first mode to balance the cell and/or in a second mode to measure a temperature of the cell. The second trace pattern may be operable in a third mode to provide power from the cell. The third trace pattern may be operable in a fourth mode to sense a voltage of the cell.

In one embodiment, a battery pack comprising a plurality of the cells is disclosed. In another embodiment, a method of manufacturing the battery pack or cell including the first, second, third traces and an electronic measurement device is disclosed.

### BRIEF DESCRIPTION OF THE DRAWINGS

To easily identify the discussion of any particular element or act, the most significant digit or digits in a reference number refer to the figure number in which that element is first introduced.

FIG. 1 depicts a drivetrain and energy storage components in accordance with illustrative embodiments.

FIG. 2 depicts a diagram of a battery pack arrangement in accordance with an illustrative embodiment.

FIG. 3 depicts a perspective view of a first cell in accordance with an illustrative embodiment.

FIG. 4 depicts another perspective view of a first cell in accordance with an illustrative embodiment.

FIG. 5 depicts another perspective view of a cell with one cap plate in accordance with an illustrative embodiment.

FIG. 6 depicts a cross-section view of a first cell in accordance with an illustrative embodiment.

FIG. 7 depicts a perspective view of a plurality of first cells in a first arrangement in accordance with an illustrative embodiment.

FIG. 8 depicts a perspective view of a plurality of first cells in a second arrangement in accordance with an illustrative embodiment.

FIG. 9 depicts a routine in accordance with one embodiment.

FIG. 10 depicts a perspective view of a second cell in accordance with an illustrative embodiment.

FIG. 11 depicts another perspective view of a second cell in accordance with an illustrative embodiment.

FIG. 12 depicts a perspective view of a plurality of second cells in a first arrangement in accordance with an illustrative embodiment.

FIG. 13 depicts a perspective view of a plurality of second cells in a second arrangement in accordance with an illustrative embodiment.

FIG. 14 depicts a perspective view of a third cell in accordance with an illustrative embodiment.

FIG. 15 depicts a sketch illustrating a circuit diagram of circuit including the third cell in accordance with an illustrative embodiment.

FIG. 16 depicts a routine in accordance with one embodiment.

FIG. 17 depicts a perspective view of a fourth cell in accordance with an illustrative embodiment.

FIG. 18 depicts a sketch illustrating a circuit diagram of circuit including a plurality of fourth cells in accordance with an illustrative embodiment.

FIG. 19 depicts a perspective view of a plurality of fourth cells in a first arrangement in accordance with an illustrative embodiment.

FIG. 20 depicts a routine in accordance with one embodiment.

FIG. 21 depicts a functional block diagram of a computer hardware platform in accordance with one embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, and/or components have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a cell. As used herein, the term “vertical” describes an orientation that is arranged perpendicular to the first surface of a cell.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

For the sake of brevity, conventional techniques related to battery cells and their fabrication may or may not be described in detail herein. Moreover, the various tasks and process steps described herein can be incorporated into a more comprehensive procedure or process having additional steps or functionality not described in detail herein.

Turning now to an overview of technologies that generally relate to the present teachings, battery cells are used in many applications including in electric vehicles and home energy storage units. The cells typically comprise an anode, a cathode, and an electrolyte placed in a protective housing. A wire or an electrical interconnect from external devices such as a control module may be connected to terminals of the cell. The illustrative embodiments recognize that such wires or interconnects may typically be run throughout a battery pack as needed such as in between cells, underneath cells, above cells, etc., to be eventually connected to terminals of the various cells of the battery pack. These routed wires may however be susceptible to interference from magnetic fields emitting from high currents in the battery pack. Further, the wires may occupy significant space in the battery pack, thus reducing the volumetric energy density of the battery pack.

The illustrative embodiments recognize that it may be desirable to reduce the volume occupied by interconnects/wires/busses and organize the configuration of the interconnects before electrically coupling them to cell terminals. This approach may be helpful in many scenarios, for example in configurations where the cell terminal may not be easily accessible or is located in hard-to-reach locations and may also provide a more robust and secure connection to the cell, which can be important in high vibration or shock situations.

The illustrative embodiments disclose a cell including a housing, a first terminal with a first polarity, the first terminal being disposed on a first cap plate at a first end of the cell. The cell also includes a second terminal with a second polarity different from the first polarity, the second terminal being disposed on a second cap plate at a second end of the cell. The second end of the cell may be opposite to the first end or the same as the first end of the cell, in which case the first cap plate and second cap plate are the same. A conductive material is disposed on at least one large wall surface of the cell and dimensioned to cover an area of the cell at the at least one large wall surface. The conductive material further includes a first extension at the first end of the cell, the first extension being electrically coupled (such as, in some cases being directly connected, as shown in the diagrams herein) to the first terminal, and a second extension at the second end of the cell, the second extension being affixed to the second cap plate at the second end of the cell.

The conductive material enables electrical coupling of a first lead and a second lead of an another device such as a BMS to the first and second terminals by electrical coupling of the first and to the second extension and second lead to the second terminal. Thus, the conductive material or wiring may be part of the cell and manufactured therewith and may deliver a connection from a terminal at one end of the cell to the other end to make both cell terminals available for connection on the same end.

In an aspect herein, the conductive material is dimensioned to provide a predetermined resistance and operated in one or more modes including a voltage sensing mode, a temperature measurement mode, or a cell balancing mode.

### Example Vehicle System

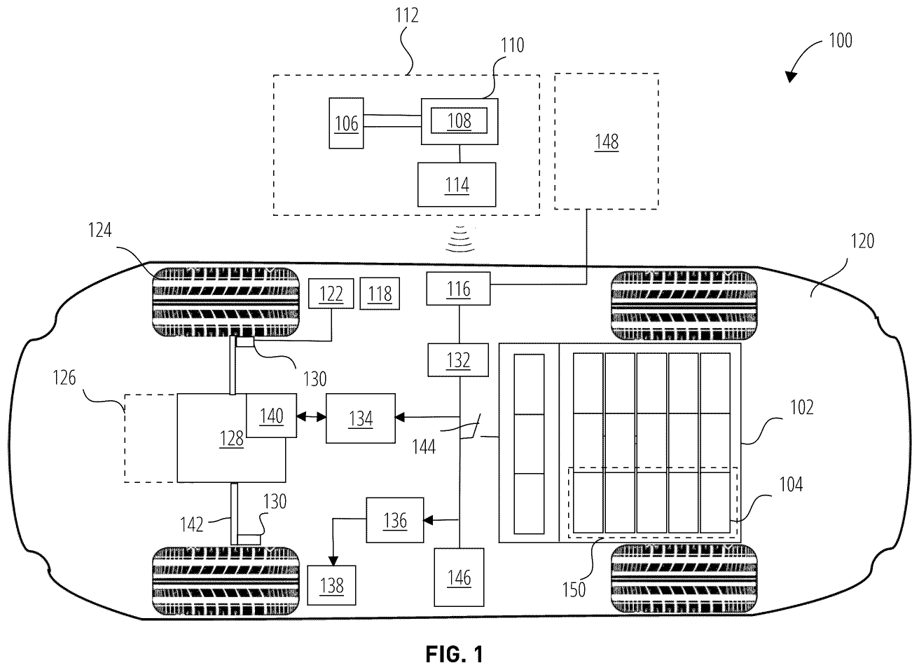

Turning to FIG. 1, a schematic of a generalized electric vehicle system 100 in which a cell 104 of a battery pack 102 may be housed will be described. It will become apparent to a person skilled in the relevant art(s) that the concepts described herein are directed to cells used in all electrified/electric vehicles, including, but not limited to, battery electric vehicles (BEV's), plug-in hybrid electric vehicles, motor vehicles, railed vehicles, watercraft, and aircraft configured to utilize rechargeable electric batteries as their main source of energy to power their drive systems propulsion or that possess an all-electric drivetrain. The cells 104 may also be used in any other application in which an energy supply is utilized, such as in a home or commercial energy storage system.

The electric vehicle 120 may comprise one or more electric machines 140 mechanically connected to a transmission 128. The electric machines 140 may be capable of operating as a motor or a generator. In addition, the transmission 128 may be mechanically connected to an engine 126, as in a PHEV. The transmission 128 may also be mechanically connected to a drive shaft 142 that is mechanically connected to the wheels 122. The electric machines 140 can provide propulsion and deceleration capability when the engine 126 is turned on or off. The electric machines 140 also act as generators and can provide fuel economy benefits by recovering energy that would normally be lost as heat in the friction braking system. The electric machines 140 may also reduce vehicle emissions by allowing the engine 126 to operate at more efficient speeds and allowing the electric vehicle 120 to be operated in electric mode with the engine 126 off in the case of hybrid electric vehicles.

A battery pack 102 stores energy that can be used by the electric machines 140. The battery pack 102 typically provides a high voltage DC output and is electrically connected to one or more power electronics modules 134. In some embodiments, the battery pack 102 comprises a traction battery and a range-extender battery. A battery pack may also include one of more modules 150 each including a plurality of cells. Terminals of cells 104 of the battery pack 102 may be tapped through one or more interconnects or conductive materials described herein. One or more contactors 144 may isolate the battery pack 102 from other components when opened and connect the battery pack 102 to other components when closed. A structure of the interconnects may be configured to eliminate unnecessary use of space as described hereinafter. This may increase the volumetric energy density of the cells and battery pack. The battery pack assembly may in some cases have a cell-to-pack configuration. For example, a battery pack configuration may include cells directly placed in an enclosure without the use of separate modules, with the enclosure also housing other hardware such as, but not limited to the power electronics module 134, DC/DC converter module 136, system controller 118 (such as a battery management system (BMS)), power conversion module 132, battery thermal management system (cooling system and electric heaters) and contactors 144. The cell 104 may have two terminals disposed at opposing ends or on the same surface of the cell 104. By minimizing a thickness of the interconnects and providing a connection from a first terminal at one end of the cell to the other end to make both cell terminals available for connection on the same end, the routing of external leads to the terminals may be better controlled and organized.

The power electronics module 134 is also electrically connected to the electric machines 140 and may provide the ability to bi-directionally transfer energy between the battery pack 102 and the electric machines 140. For example, a traction or range-extender battery may provide a DC voltage while the electric machines 140 may operate using a three-phase AC current. The power electronics module 134 may convert the DC voltage to a three-phase AC current for use by the electric machines 140. In a regenerative mode, the power electronics module 134 may convert the three-phase AC current from the electric machines 140 acting as generators to the DC voltage compatible with the battery pack 102. The description herein is equally applicable to a BEV. For a BEV, the transmission 128 may be a gear box connected to an electric machine 140 and the engine 126 may not be present.

In addition to providing energy for propulsion, the battery pack 102 may provide energy for other vehicle electrical systems. A typical system may include a DC/DC converter module 136 that converts the high voltage DC output of the battery pack 102 to a low voltage DC supply that is compatible with other vehicle loads. Other electrical loads 146, such as compressors and electric heaters, may be connected directly to the high voltage without the use of a DC/DC converter module 136. The low-voltage systems may be electrically coupled to an auxiliary battery 138 (e.g., a 12V battery).

The battery pack 102 may be recharged by a charging system such as a wireless vehicle charging system 112 or a plug-in charging system 148. The wireless vehicle charging system 112 may include an external power source 106. The external power source 106 may be a connection to an electrical outlet. The external power source 106 may be electrically coupled to electric vehicle supply equipment 110 (EVSE). The electric vehicle supply equipment 110 may provide an EVSE controller 108 to provide circuitry and controls to regulate and manage the transfer of energy between the external power source 106 and the electric vehicle 120. The external power source 106 may provide DC or AC electric power to the electric vehicle supply equipment 110. The electric vehicle supply equipment 110 may be coupled to a transmit coil 114 for wirelessly transferring energy to a receiver 116 of the vehicle 120 (which in the case of a wireless vehicle charging system 112 is a receive coil). The receiver 116 may be electrically coupled to a charger or on-board power conversion module 138. The receiver 116 may be located on an underside of the electric vehicle 120. In the case of a plug-in charging system 148, the receiver 116 may be a plug-in receiver/charge port and may be configured to charge the battery pack 102 upon insertion of a plug-in charger. The power conversion module 132 may condition the power supplied to the receiver 116 to provide the proper voltage and current levels to the battery pack 102. The power conversion module 132 may interface with the electric vehicle supply equipment 110 to coordinate the delivery of power to the electric vehicle 120.

One or more wheel brakes 130 may be provided for decelerating the electric vehicle 120 and preventing motion of the electric vehicle 120. The wheel brakes 130 may be hydraulically actuated, electrically actuated, or some combination thereof. The wheel brakes 130 may be a part of a brake system 122. The brake system 122 may include other components to operate the wheel brakes 130. For simplicity, the figure depicts a single connection between the brake system 122 and one of the wheel brakes 130. A connection between the brake system 122 and the other wheel brakes 128 is implied. The brake system 122 may include a controller to monitor and coordinate the brake system 122. The brake system 122 may monitor the brake components and control the wheel brakes 130 for vehicle deceleration. The brake system 122 may respond to driver commands and may also operate autonomously to implement features such as stability control. The controller of the brake system 122 may implement a method of applying a requested brake force when requested by another controller or sub-function.

### Example Power Supply System

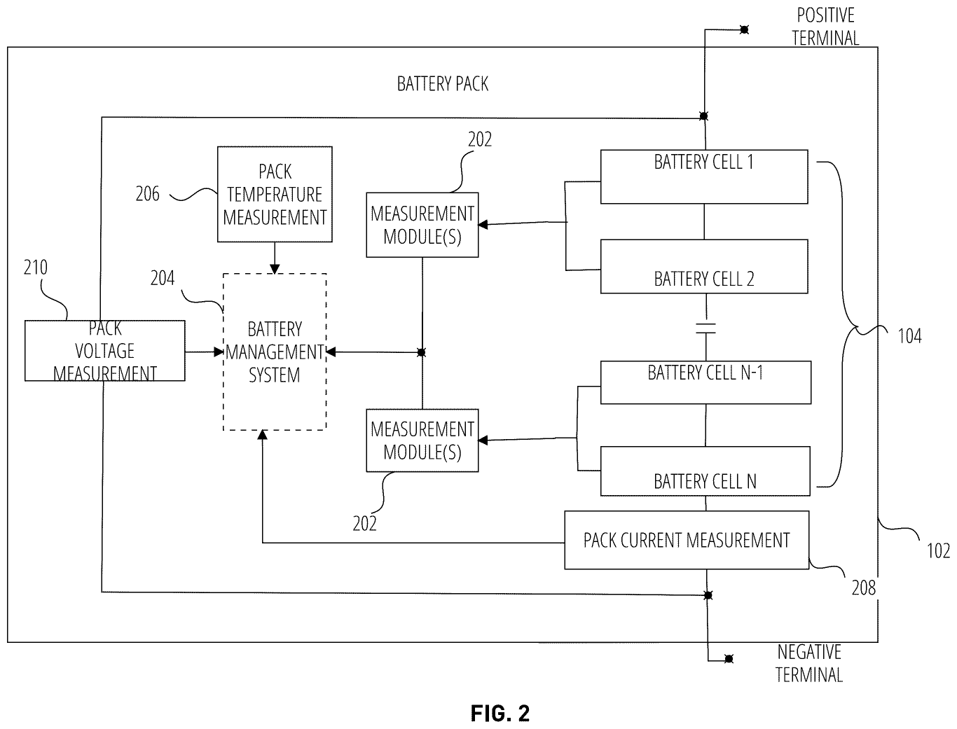

Turning now to FIG. 2, an example power supply system in which the cell 104 is employed is disclosed. The system may be a battery pack 102 comprising a plurality of cells 104 with integrated conductive material. FIG. 2 shows a schematic of the battery pack 102 in a simple series configuration of N cells 104. Other battery pack configurations, however, may be composed of any number of individual battery cells coupled in series or in parallel or in some combination thereof. The battery pack 102 may also have controllers such as the battery management systems (BMS 204) that monitors and controls the performance of the cells 104 and/or battery pack 102. The BMS 204 may monitor several battery pack level characteristics such as pack current 208, short circuits, pack voltage 210 and pack temperature 206. The BMS 204 may have non-volatile memory such that data may be retained when the BMS 204 is in an off condition. Retained data may be available upon the next key cycle.

In addition to monitoring the pack level characteristics, there may be cell 104 level characteristics that are measured and monitored. For example, the terminal voltage, current, and temperature of each cell 104 may be measured as discussed herein. A system may use a measurement module(s) 202 to measure the cell 104 characteristics. Depending on the capabilities, the measurement module(s) 202 may measure the characteristics of one or multiple of the cells 104. Each measurement module(s) 202 may transfer the measurements to the BMS 204 for further processing and coordination. The measurement module(s) 202 may be as simple as one or more switches or leads operated to provide a coupling to the one or more cells. The measurement module(s) 202 may transfer signals in analog or digital form to the BMS 204. In some embodiments, the measurement module(s) 202 functionality may be incorporated internally to the BMS 204. That is, the measurement module(s) 202 hardware may be integrated as part of the circuitry in the BMS 204 and the BMS 204 may handle the processing of raw signals. The measurement module(s) 202 may in some cases be embodied in the form of an electronic measurement device disposed on each of the cells as discussed herein. It may be useful to calculate various characteristics of the battery pack. Quantities such a battery power capability and battery state of charge may be useful for controlling the operation of the battery pack as well as any loads receiving power from the battery pack.

### Voltage Sensing

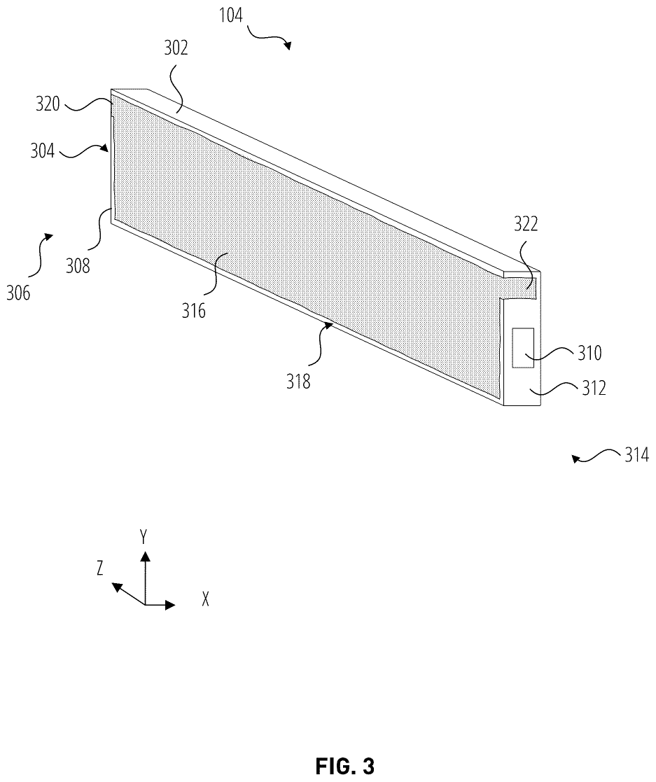

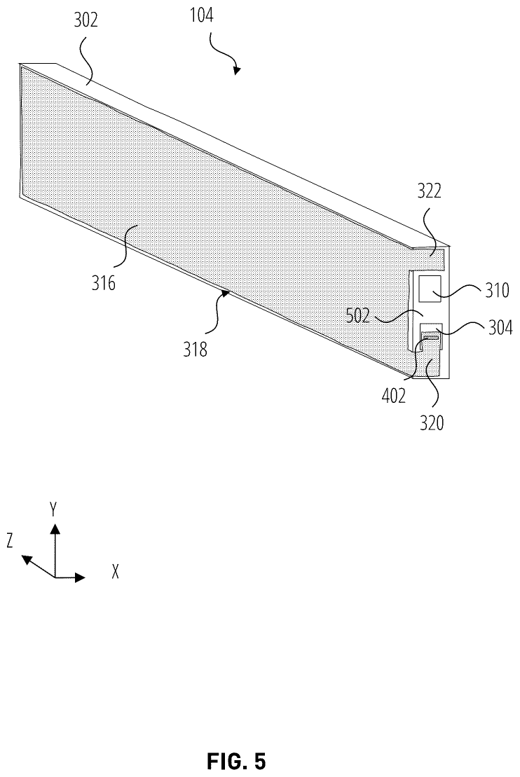

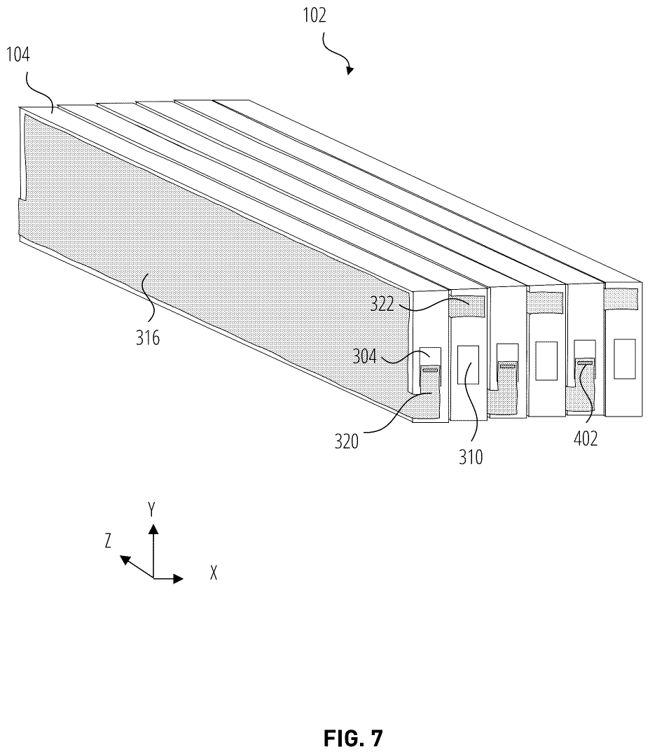

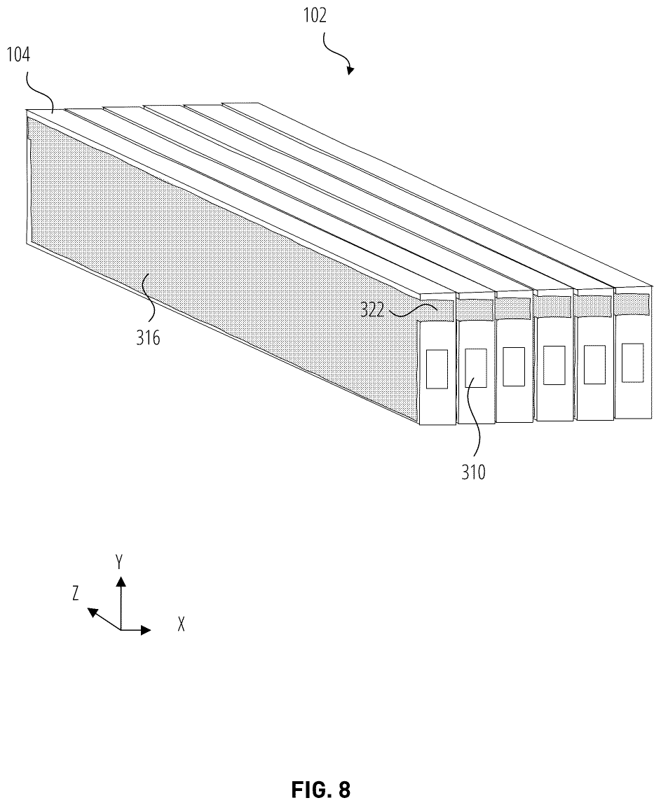

FIG. 3 illustrates a perspective view of the cell 104 in accordance with an illustrative embodiment. The cell comprises a housing 302 extending along a first axis (e.g., the Y-axis) to define a width, a second axis (e.g., the Z-axis) orthogonal to the first axis to define a length, and a third axis (e.g., the X-axis) orthogonal to the first and second axes to define a thickness. The cell 104 further comprises a first terminal 304 that has a first polarity, the first terminal 304 being disposed on a first cap plate 308 at a first end 306 of the cell 104. The cell 104 also comprises a second terminal 310 that has a second polarity different from the first polarity. The second terminal 310 is disposed on a second cap plate 312 at a second end 314 of the cell 104 opposite to the first end 306 or on the same end as the first end of the cell, in which case the first cap plate 308 and second cap plate 312 may be the same entity. More specifically, the terminals may be located on the same surface or same cap plate 502 of the cell and spread apart from each other as shown in FIG. 5. Turning back to FIG. 3, the cell 104 also comprises a conductive material 316 disposed on at least one of the two opposing large wall surfaces of the cell. The conductive material may be any conductive material such as screen-printed conductive inks or epoxies, conductive foils, conductive films, or conductive printed material or otherwise other conductive material. A large wall surface herein may refer to the cell surface shown in FIG. 3 for example, that lies parallel to the YZ plane of FIG. 3. The YZ plane as used in the disclosure is a two-dimensional plane in three-dimensional space that is perpendicular to the X-axis and more specifically a two-dimensional plane in three-dimensional space that is perpendicular to a surface of the cell on which a terminal lies. The conductive material 316 may be dimensioned to cover or substantially cover a whole area of the cell at the large wall surface 318. However, the conductive material 316 may alternatively be dimensioned to cover a smaller area of the large wall surface 318. The dimensioning of the conductive material may be such that a predetermined resistance of the conductive material is achieved. Further, the dimensioning may be such that a predetermined thickness of the conductive material is achieved. This may reduce unused space otherwise occupied by conventional wires in a module or battery pack (see FIG. 7 and FIG. 8) comprising a plurality of the cells.

The conductive material 316 may comprise a first extension 320 at the first end 306 of the cell, the first extension being electrically coupled to the first terminal 304. The conductive material 316 may also comprise a second extension 322 at the second end 314 of the cell 104, the second extension 322 being affixed to the second cap plate 312 at the second end 314 of the cell 104. The first and second extensions may be contiguous with the conductive material 316.

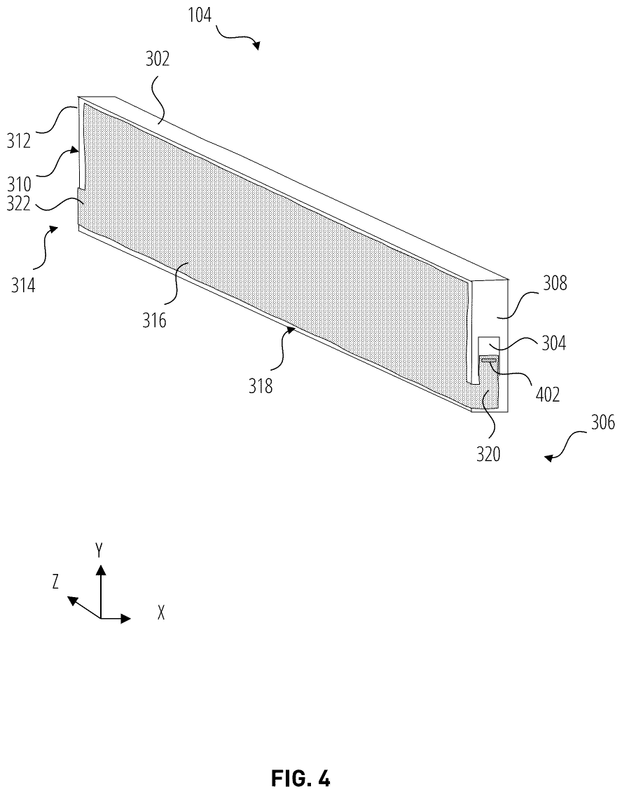

FIG. 4 illustrates the first end 306 of the cell 104. At the first end, the first extension 320 may be electrically coupled (such as being directly or electrically connected) with the first terminal 304 through any electrical connections such as by the use of a weld 402 or a low resistance electrical connection.

In the embodiment of FIG. 3 and FIG. 4, the cell 104 with the conductive material 316 may be manufactured for use in sensing a voltage of the cell 104. Thus, the conductive material may be dimensioned to provide a predetermined resistance for sensing the voltage of the cell 104. By connecting leads (not shown) of a measurement module such as an external measurement module or BMS 204 to the second terminal 310 at the second end 314 and to the first terminal 304 through the second extension 322 of the conductive material 316 at the same second end 314, a voltage of the cell may be measured while reducing unnecessary use of space due to tapping of the terminals from the same end of the cell.

In an example, a plurality of cells may be large format cells arranged in an alternating fashion. Thus, the positive and negative terminals may be located next to each other. The large distances between cell terminals may however not be an issue as the need to use long sense wires/leads along with the large loop areas created therefrom is eliminated or at least significantly reduced. Connections from a BMS control module may thus be terminated at one side of the cells at locations near each other. This may enable the areas occupied by the leads to be small and less susceptible to interference from electromagnetic fields emitting from high currents flowing through the plurality of cells. Otherwise, using configurations wherein relatively large area are occupied by the leads may create an antenna that can pick up electrical noise, which may be coupled into the pack level and cell level measurements and disturb the measurement accuracy. Electric vehicles have significant electrical noise that is very undesirable not only from a measurement perspective, but also from a mechanical perspective. By the configuration described herein, even one bundle of wiring/leads from a control module may be enough for coupling to the plurality of cells.

Advantageously, the integrated conductive materials may further remove, or at least reduce pressure points along the wall surfaces of the cells while still maximizing volumetric efficiency. More specifically, conventional wires placed between cells 104 or around the edges of cells may create pressure points. As conventional packs become compressed, the wires end up getting squeezed and over time pose safety issues. The conductive materials 316 of the illustrative embodiments may be evenly distributed over the whole large wall surfaces of the cell. This may address any issues of pressure points or compression.

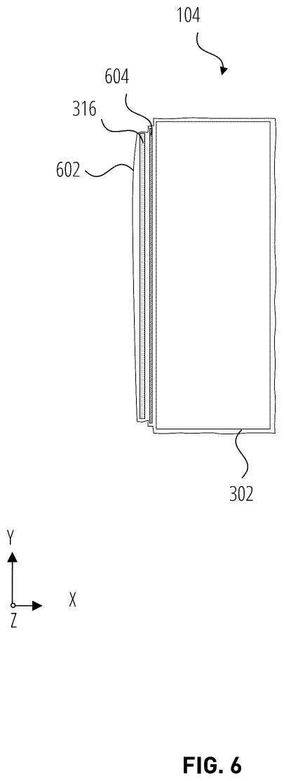

As shown in FIG. 6, which illustrates a cross-section view through the YX-plane, the cell 104 may be further comprise a cell wrap film 602, and an insulating film 604. The insulating film 604 may be disposed between the conductive material 316 and the large wall surface of the housing 302. The cell wrap film 602 may be configured to wrap an exposed periphery of the conductive material, the insulating film, and the housing upon assembly of the conductive material 316 and the insulating film 604 onto the large wall surface. The cell wrap film may be heat shrunk to form the outer protective layer. In some embodiments, an area of the insulating film can be slightly larger than the area of the conductive material to prevent shorting. Further, the conductive material 316 may be die-cut and the cell wrap film 602 may be thicker than the insulating film 604. In an embodiment, the insulating film 604 is a liner that is manufactured with the conductive material 316 and placed over it. One end of the insulating film 604 may have a peelable material that may be peeled off to stick the insulating film 604 with the conductive material 316 onto the housing. This may be performed during manufacturing of the cell by a cell assembly machine. The thicknesses of the conductive materials 316 described throughout the disclosure may be, for example, less than 0.25 mm (such as between about 0.1 mm and about 0.25 mm). In another example, the trace pattern 1002 may be less than or equal to about 10% or about 5% or about 2% or more specifically about 1% of the thickness of the cell. The thickness of the trace pattern may also be greater than about 0.1% of the thickness of the cell. The term “about” as used herein can include a range of ±8% or 5%, or 2% of a given value.

In one aspect, the first terminal 304, the first extension 320, the second extension 322 have the first polarity, and the second terminal and has the second polarity different from the first polarity. In another aspect, the cell may be a large-format cell wherein the length of the cell may be about 400 mm (e.g., 400 mm +/−5% to +/−β10%). In an illustrative embodiment, the dimensions of the cells may be about 400 mm×120 mm×18 mm (i.e., up to +/−5% or up to +/−10% for the length, width, and thickness respectively). Of course, other dimensions may be possible in view of the descriptions herein. The thickness of the conductive material (in the X-axis) may be uniform or substantially uniform (e.g., within 5% or 2% or 1% of a value). Further, the conductive material may comprise copper or aluminum or other suitable material (such as a conductive polymer or another metal) and the cell may comprise a housing that comprises aluminum or steel.

FIG. 7 illustrates a battery pack comprising a plurality of cells 104. The plurality of cells may be arranged in an alternating fashion such that opposite terminals are adjacent to each other. The plurality of cells 104 may alternatively be arranged in any manner as required by a pack or module. For example, the plurality of cells may be arranged in the same direction as shown in FIG. 8.

Turning back to FIG. 7, the battery pack 102 comprises a plurality of cells, each cell 104 of the plurality of cells further comprises the housing 302 which extends along a first axis (e.g., the Y-axis) to define a width, a second axis (e.g., the Z-axis) orthogonal to the first axis to define a length, and a third axis (e.g., the X-axis) orthogonal to the first and second axes to define a thickness. Each cell of the plurality of cells further includes a first terminal 304 with a first polarity, the first terminal 304 being disposed on a first cap plate 308 at a first end of the cell. The battery pack also includes a plurality of cells, each cell of the plurality of cells further includes a second terminal 310 with a second polarity different from the first polarity, the second terminal being disposed on a second cap plate that is opposite to the first cap plate or the same as the first cap plate. Each cell of the plurality of cells may further includes a conductive material disposed on one or more of the large wall surfaces of the cell, the large wall surface being parallel to the YZ plane as shown in the figures. The conductive of each cell of the plurality of cells may further comprise a first extension at the first end of the cell, the first extension being electrically coupled to the first terminal, and a second extension at the second end of the cell, the second extension being affixed to the second cap plate at the second end of the cell. The conductive materials 316 of the plurality of cells may each be dimensioned to provide a predetermined resistance for sensing a voltage of the respective cell.

In an aspect herein, the battery pack 102 may also comprise an external voltage sensing device (not shown), and for each cell of the plurality of cells, a first lead and a second lead of the voltage sensing device may be electrically coupled to the first and second terminals by electrical coupling of the first and second leads to the second extension 322 and the second terminal 310 respectively. In some cases, the voltage sensing device may be a BMS.

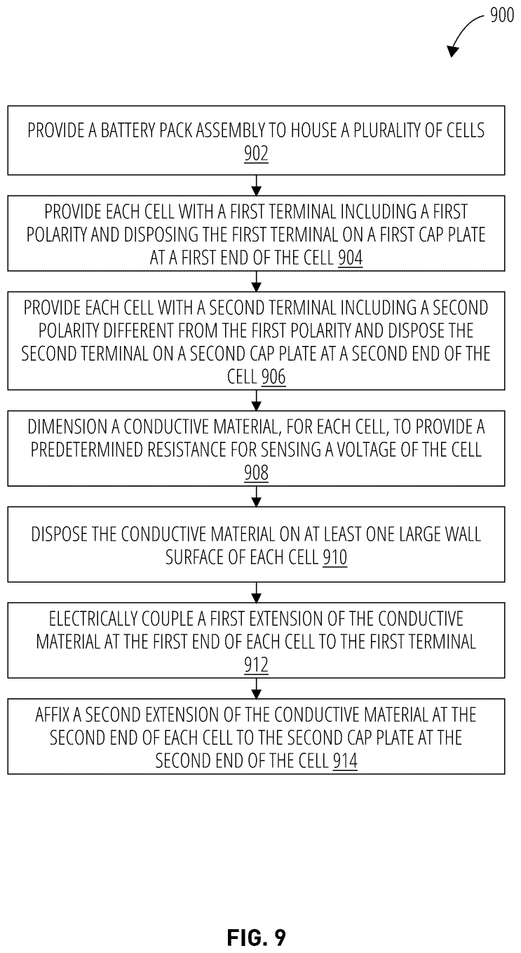

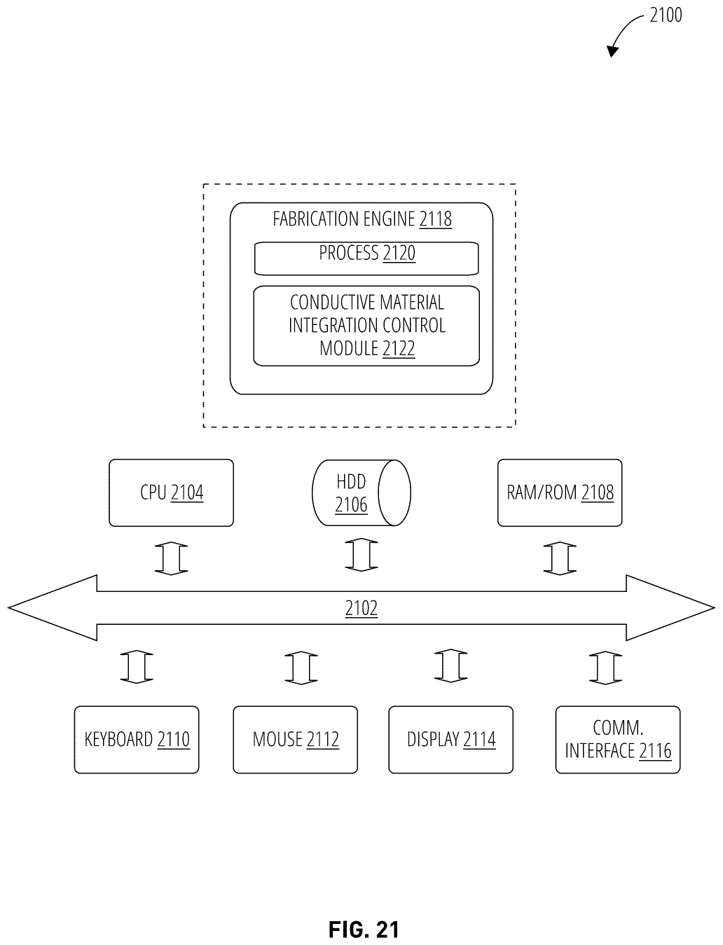

Turning now to FIG. 9, a flow chart of a routine 900 for manufacturing a battery pack or cell 104 is disclosed. The routine may be performed with the fabrication engine 2118 of FIG. 21. In block 902, fabrication engine 2118 may provide a battery pack assembly that may house a plurality of cells. Each cell 104 of the plurality of cells may comprise, as discussed herein, a housing 302. In block 904, fabrication engine 2118 may provide each cell with a first terminal disposed at one end of the cell. In block 906, fabrication engine 2118 may also provide each cell with a second terminal disposed at a second end of the cell which second end may be the same as the first end or opposite to the first end. In block 908, fabrication engine 2118 may dimension a conductive material 316, for each cell, to provide a predetermined resistance that may be usable to sense a voltage of the cell. In block 910, fabrication engine 2118 may dispose the conductive material on at least one large wall surface of each cell, the at least one large wall surface being parallel to the YZ plane. The conductive material may be insulated from the housing using an insulating film. The cell with the conductive material and insulating film may then be wrapped in a cell wrap film to produce a wrapped cell. In block 912, fabrication engine 2118 may electrically couple a first extension of the conductive material at the first end of each cell to the first terminal. In block 914, fabrication engine 2118 may affix a second extension of the conductive material at the second end of each cell to the second cap plate at the second end of the cell. The insulating film may insulate the second extension from the cap plate. However, the first extension may be electrically coupled or electrically connected to the first terminal and thus be at a same polarity as the polarity of the first terminal.

In an aspect, the routine 900 further includes, electrically coupling a first lead and a second lead of a voltage sensing device to the first and second terminals of one or more cells by electrically coupling the first and second leads to the second extension and the second terminal of the one or more cells respectively.

### Balancing and Temperature Measurement

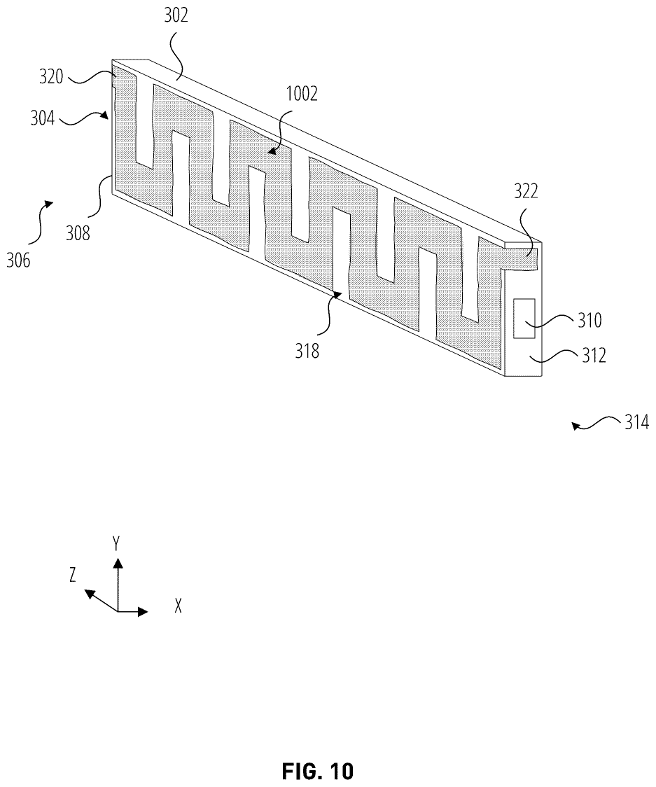

FIG. 10 illustrates a perspective view of a cell 104 wherein the conductive material is patterned. The cell comprises a housing extending along a first axis (e.g., Y-axis of FIG. 10) to define a width, a second axis (e.g., Z-axis of FIG. 10) orthogonal to the first axis to define a length, and a third axis (e.g., X-axis of FIG. 10) orthogonal to the first and second axes to define a thickness. The cell also includes a first terminal 304 with a first polarity, the first terminal being disposed on a first cap plate 308 at a first end 306 of the cell. The cell also includes a second terminal 310 with a second polarity different from the first polarity, the second terminal 310 being disposed on a second cap plate 312 at a second end 314 of the cell 104. The cell also includes a conductive material which may be patterned into a trace pattern 1002, the trace pattern 1002 being disposed on at least one large wall surface 318 of the cell 104 and the trace pattern 1002 configured to optimize a net effective contact area and a uniform heat dissipation of the trace pattern, the at least one large wall surface being parallel to the YZ plane shown in, for example, FIG. 10. The trace pattern 1002 may further include a first extension 320 at the first end of the cell, the first extension 320 being electrically coupled to the first terminal 304, and a second extension 322 at the second end 314 of the cell, the second extension 322 being affixed to the second cap plate 312 at the second end 314 of the cell 104. Of course, the terminals may be on the same cap plate in which case the first and second extensions may be on the same end similarly to the configuration of FIG. 5. As shown in FIG. 10, the trace pattern may have empty areas between a plurality of adjacent sections of the trace pattern. The empty areas may force current through the remaining pattern.

In an aspect, the trace pattern 1002 may be dimensioned to provide a predetermined resistance for balancing the cell 104. The trace pattern 1002 may also be used in a temperature measurement mode wherein the temperature of a cell that includes the trace pattern 1002 may be computed based on a measurement of the resistance of the trace pattern.

The trace pattern shaped to have a one or more of a serpentine pattern, a square wave pattern, a spiral pattern, and a zig zag pattern or other pattern suitable for producing a predetermined resistance. In one or more illustrative embodiments, the trace pattern may be unibody. A net effective contact area of the trace pattern 1002 may be that at least 80% or at least 90% of the at least one large wall surface. Further, the predetermined resistance of the trace pattern 1002 or otherwise conductive material may be a function of a thickness, a conductivity and/or a shape of the trace pattern 1002.

Likewise, to the cell of FIG. 3, the cell of FIG. 10 may also comprise an insulating film disposed between the trace pattern 1002 and the housing 302, as well as cell wrap film 602 configured to wrap an exposed periphery of the trace pattern 1002, the insulating film 604, and the housing 302 into a wrapped cell.

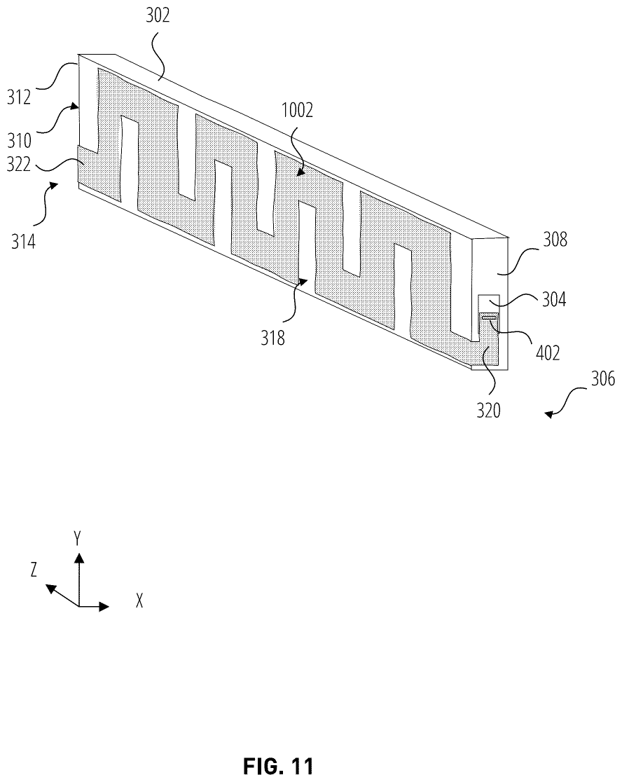

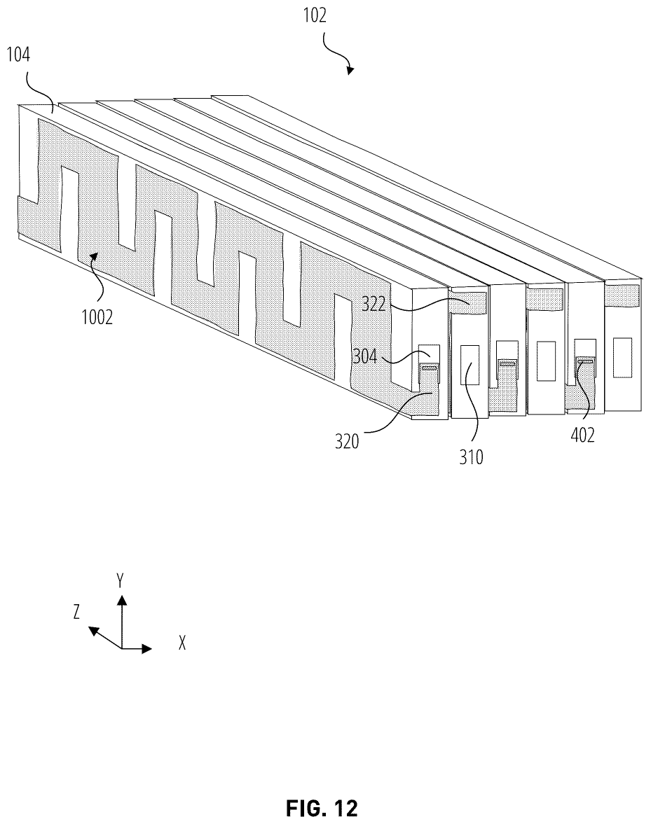

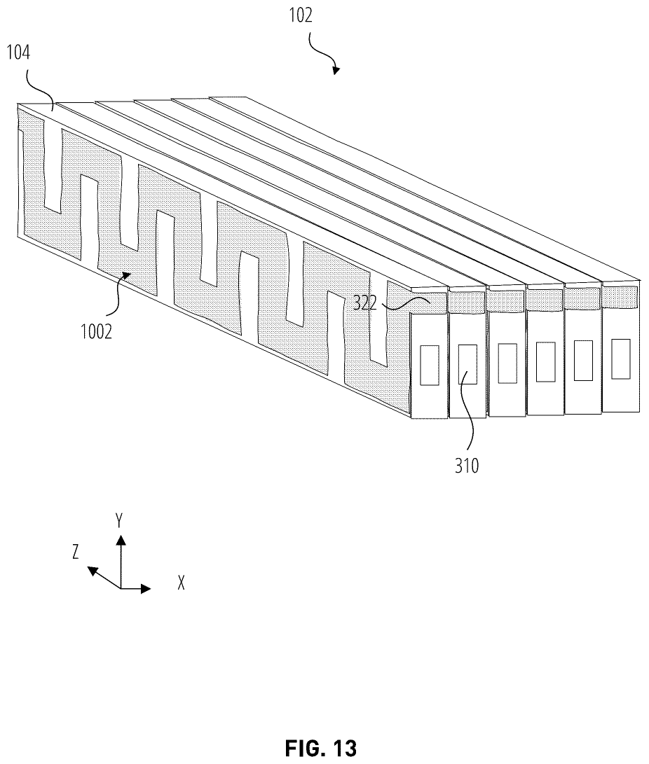

FIG. 11 illustrates a perspective view of a cell depicting a first end 306 of the cell, wherein the first extension 320 is electrically coupled to the first terminal 304. In FIG. 12 and FIG. 13 illustrate a perspective view of a battery pack 102. As shown in FIG. 12, the cells may be arranged such that terminals with opposite polarities are adjacent. Likewise, as shown in FIG. 13, the cells may be arranged such that terminals with the same polarities are adjacent. Alternatively, the cells may be arranged in any configuration that may be useful for a battery pack application.

The battery pack may include a plurality of cells, each cell of the plurality of cells further includes a housing extending along a first axis to define a width, a second axis orthogonal to the first axis to define a length, and a third axis orthogonal to the first and second axes to define a thickness. Each cell of the plurality of cells further includes a conductive material that comprises a trace pattern, the trace pattern being disposed on at least one large wall surface of the cell and the trace pattern configured to optimize a net effective contact area and a uniform heat dissipation of the trace pattern, the at least one large wall surface being parallel to the YZ plane as shown in FIG. 12. Of course, the battery pack may also include other types of cells which may not be exclusive to the cells described herein.

In one or more illustrative embodiments of the battery pack 102, a cell balancing device (not shown), may be provided wherein for at least one cell of the plurality of cells, the cell balancing device is operable to electrically couple the second extension 322 to the second terminal 310 to dissipate as heat a current or energy of at least one cell to a predetermined level. Thus, the trace pattern 1002 may be operated as a balance resistor by electrically coupling the trace pattern in parallel with the respective cell to control the voltage of the cell. One or more cells of the battery pack may be balanced such that all cells of a plurality of cells may have a voltage equal to that of a cell with the lowest voltage. Thus, the trace pattern 1002 may serve as a resistor that is mounted to the side of the cell out of, for example, a piece of foil. Advantageously, heat that is generated when balancing the cell, which would otherwise have been concentrated in a relatively small area on an electronic board, may now be uniformly distributed over the cell surface. As the cell 104 may have a high thermal mass, efficient dissipation of the heat into the thermal mass of the cell may be achieved. Further, due to control over dimensioning of the cell to cover a large area of the large wall surface, the trace pattern, can be designed to carry significant current relative to that of a discrete resistor on an electronic board which may allow faster balancing of the battery pack and thus getting the plurality of cells to have equal voltages more quickly relative to that of conventional balance resistors. The current carrying capability may be higher than that of conventional balance resistors because the high heat transfer capability into the cell's mass, as opposed to conventional balance resistors that are relatively smaller and thus have low thermal heat transfer capability. In an example, 1 amp of balance current may dissipate 3.6 W of power in a typical balance resistor which may have a corresponding thermal load of 1 W/cm\hat{ }2. Dissipating 3.6 W in the trace pattern 1002 may advantageously generate a thermal load of 0.0075 W/cm\hat{ }2.

In one further aspect, a bad or unhealthy cell among the plurality of cells may be discharged upon detecting a flaw or failure mode thereof. The higher current may be used to discharge the cell at a quicker rate, so a safe state of the battery can be achieved faster.

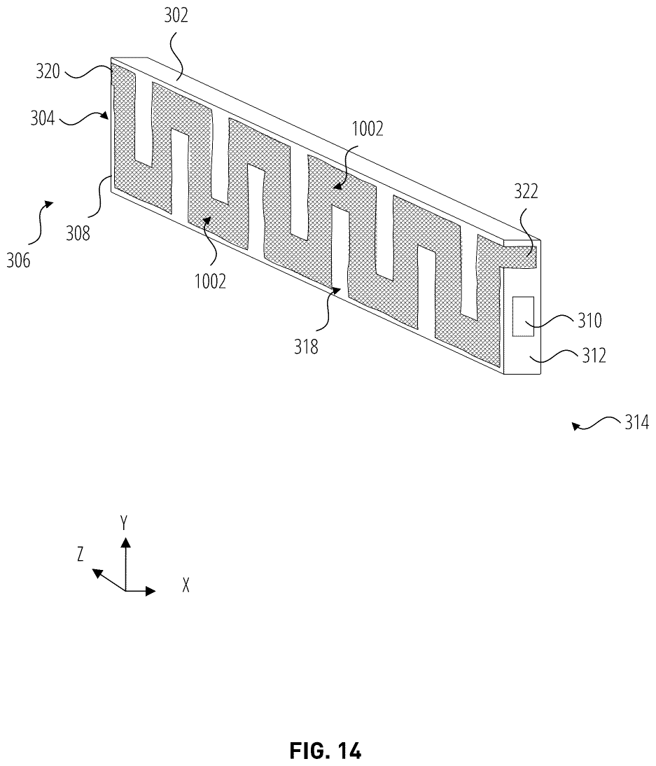

The battery pack may also be operated in an alternative mode for cell temperature measurement, wherein for at least one or all cells of the plurality of cells, the cell temperature measurement device is operable to compute a temperature of the cell by measuring a resistance of the trace pattern 1002. The cell may be the same cell as that used for balancing or may be a different cell (see FIG. 14, which shows a cell with a trace pattern used for temperature computations).

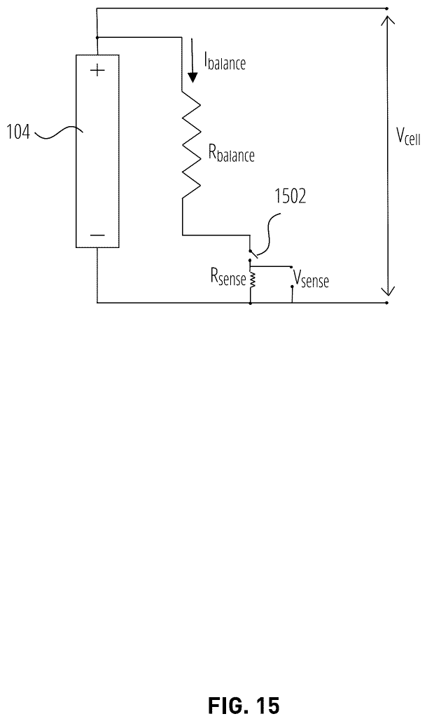

Measuring a temperature of individual conventional cells in a battery pack may be atypical. However, by measuring not every cell temperature, an overheated cell that poses a safety issue may be missed or at best untimely confirmed since heat travels relatively slowly through large thermal masses. In these cases, determining the temperature of individual cells may be critical to ensuring the safety of the battery pack or module. When current passes through the trace pattern 1002, heat may be generated. When no current is flowing through the trace pattern 1002, the temperature of the cell may match that of the trace pattern due to the trace pattern being thin relative to the thickness of the cell and/or the trace pattern 1002 having a coefficient of conductivity that is temperature sensitive. In an embodiment, the thickness of the trace pattern 1002 may less than 0.25 mm (such as between about 0.1 mm and about 0.25 mm). In another example, the trace pattern 1002 may be less than or equal to about 10% or about 5% or about 1% of the thickness of the cell. In an illustrative embodiment of measuring a temperature of a cell of the plurality of cells, a short pulse of current may be pulsed through trace pattern 1002 to measure that current using a known resistance value as described herein and as illustrated in FIG. 15. With a measurement of cell voltage and the current that is flowing through the trace pattern 1002, as well as a resistance of the trace pattern 1002, the temperature T_{c} can be computed accordingly. An example temperature computation may comprise the use of the equations:

$${T}_{c} = {T}_{0} + \frac{( {R}_{b a l a n c e} - {R}_{T 0} )}{{T}_{R}}$$

wherein

$${R}_{b a l a n c e} = \frac{{V}_{c e l l} - {V}_{s e n s e}}{{I}_{b a l a n c e}}$$

is the resistance of the trace pattern at a time that a temperature measurement is being made, V_{cell} is the voltage across the cell, I_{balance} is the current passing through the precision resistor Rₛₑₙₛₑ (see FIG. 15), R_{T0} is the resistance of the trace pattern at a known temperature T₀, T₀ is the temperature at which R_{T0} is recorded as a calibration value, and T_{R} is the temperature coefficient of resistance of the trace pattern material. T₀ may be unique for each trace pattern.

In an aspect, the cell balancing device and/or the cell temperature measurement device may be a BMS.

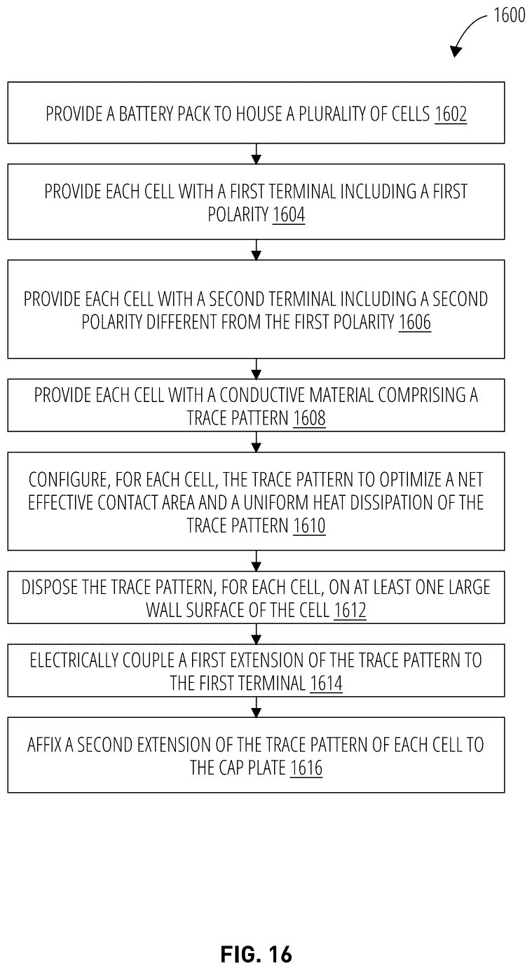

Turning now to FIG. 16, a flow chart of a routine 1600 for manufacturing a battery pack or plurality cells 104 is disclosed. The routine may be performed with the fabrication engine 2118 of FIG. 21. In block 1602, fabrication engine 2118 may provide a battery pack 102 that may house a plurality of cells. In block 1604, fabrication engine 2118 may generate the plurality of cells by providing each cell with a first terminal including a first polarity and disposing the first terminal on a first cap plate. In block 1606, fabrication engine 2118 may provide each cell with a second terminal including a second polarity different from the first polarity and dispose the second terminal on either a second cap plate at an opposite end of the cell or on the same cap plate as that of the first terminal.

In block 1608, fabrication engine 2118 may provide each cell with a conductive material comprising a trace pattern. In block 1610, fabrication engine 2118 may configure, for each cell, the trace pattern 1002 to optimize a net effective contact area and a uniform heat dissipation of the trace pattern, the at least one large wall surface being parallel to the YZ plane. The trace patterns of the individual cells may be configured to be similar or different as desired. In block 1612, fabrication engine 2118 may dispose the trace pattern, for each cell, on at least one large wall surface of the cell. In block 1614, fabrication engine 2118 may electrically couple a first extension 320 of the trace pattern at the first end of each cell to the first terminal. In block 1616, fabrication engine 2118 may affix a second extension 322 of the trace pattern at the second end of each cell to the second cap plate at the second end of the cell or to the same first cap plate in the case where the terminals are on the same end of the cell.

The routine 1600 may further include patterning the trace pattern, for each or at least one cell, to provide a predetermined resistance for balancing the cell, and for at least one cell of the plurality of cells, electrically coupling, by a cell balancing device the second extension to the second terminal to dissipate as heat an energy of the at least one cell to a predetermined level.

The method may also include for each or at least one cell of the plurality of cells, operating a cell temperature measurement device, to compute a temperature of the cell by measuring a resistance of the trace pattern.

Advantageously, the conductive materials described herein may be disposed on both large wall surfaces 318 of the cell or even in some cases on the small wall surfaces as needed. Further the first polarity may be positive in which case the second polarity is negative. The first polarity may alternatively be negative in which case the second polarity is positive.

Integrated Device with Integrated Electronic Measurement

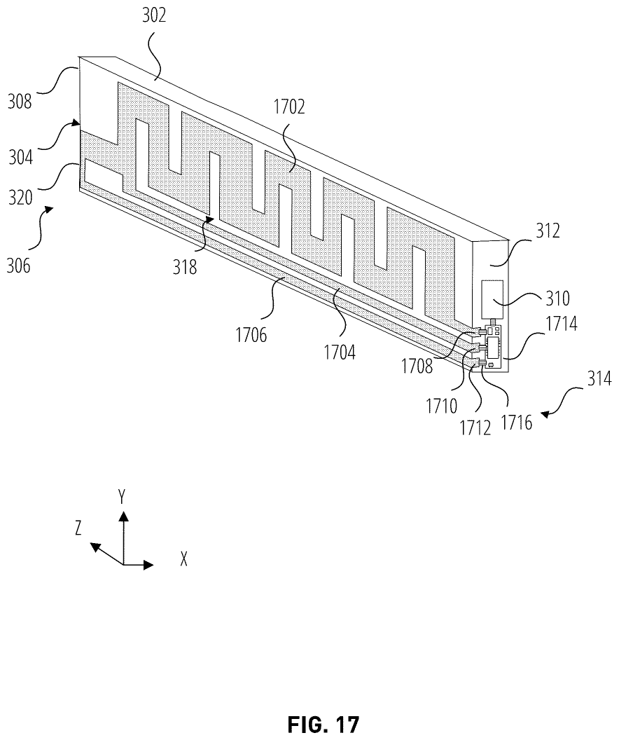

FIG. 17 discloses a cell comprising a plurality of trace patterns and an integrated electronic measurement device 1714. Each trace pattern may be configured for a specific purpose. The illustrative embodiments recognize that the process of optimizing the design and volumetric energy density of battery packs may be greatly enhanced by integrating an electronic board onto cells while addressing heat dissipation issues. This may significantly reduce the number of wires routed throughout the battery pack for communication and control. The illustrative embodiments further recognize that when the electronic board is able to perform balancing, temperature measurement, and voltage sensing, with challenges related to overheated on-board resistors being remedied, not only may even more space may be saved but battery pack safety may also be enhanced due to the highly integrated design and heat generation in the electronic board being alleviated by the disposition of the resistors on the cell rather than on the electronic board. The dimensioning of the resistors to comprise a flat thin profile may also enable faster heat dissipation as described herein.

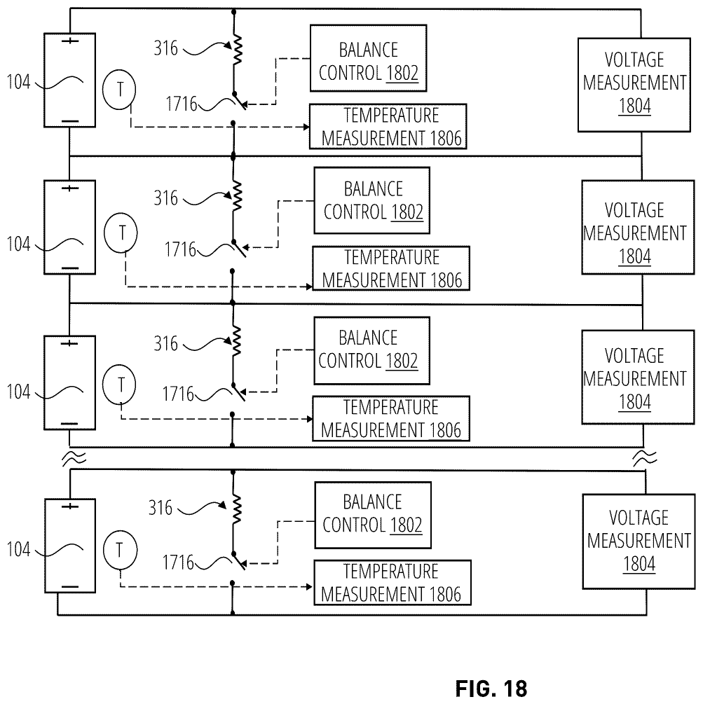

The illustrative embodiments disclose a cell, as shown in FIG. 17-FIG. 18, that comprises a housing 302 extending along a first axis to define a width, a second axis orthogonal to the first axis to define a length, and a third axis orthogonal to the first and second axes to define a thickness. The cell comprises a first terminal 304 with a first polarity, the first terminal 304 being disposed on a first cap plate at a first end of the cell and a second terminal 310 with a second polarity different from the first polarity, the second terminal 310 being disposed on a second cap plate 312 at a second end of the cell or on the same first cap plate 308 at the first end 306 of the cell. The cell further comprises a conductive material that includes a first trace pattern 1702, a second trace pattern 1704 and a third trace pattern 1706 each trace pattern having a first extension electrically coupled together and further electrically coupled the first terminal. Each trace pattern may also comprise a second extension separated from each other on the second cap plate, which may be the same as the first cap plate. The second extensions of the trace patterns may be isolated from each other with each being separately electrically coupled to respective contacts of the electronic measurement device 1714. Specifically, the third trace pattern 1706 may be electrically coupled to a contact of the electronic measurement device 1714 via a second switch 1716.

In an aspect herein, the first trace pattern may be operable in a first mode to balance the cell and/or in a second mode to measure a temperature of the cell. Alternatively distinct trace patterns may be used for balancing and temperature measurement. The second trace pattern 1704 may be operable in a third mode to provide power from the cell to power the electronic measurement device 1714. The third trace pattern may be operable in a fourth mode as a Kelvin connection to sense a voltage of the cell, in which case there is little to no voltage drop across the third trace pattern.

In as aspect, the trace patterns may be dimensioned to have different resistances and/or shapes. More specifically, the first trace pattern 1702 may be dimensioned to have a relatively low resistance (for example between about 0.5 ohm to 5 ohm) relative to the resistance of conventional balancing resistors (for example between 10 ohm to 100 ohm) to achieve relatively higher balance currents. The second trace pattern 1704 may be dimensioned to have a relatively low resistance relative to the resistance of the first trace pattern 1702. The third trace pattern may be dimensioned to have a resistance that is typically lower than the resistance of the first trace pattern and higher than the resistance of the second trace pattern. Even more specifically, the effective resistance of the first trace pattern 1702 may be many times (for example about, 80 times, 100 times, 200 times or even higher) larger than resistance of the third trace pattern 1706, and the resistance of the second trace pattern 1704 may be several times (e.g. About 8 times, or about 10 times) less than the resistance of the third trace pattern 1706. Of course, these examples may not be limiting as other examples and relative resistances may be obtained based on specific functions desired and in view of the descriptions. Thus, the resistances may be functions of the geometry of trace patterns and may be application dependent. The first trace pattern 1702 may be at least one of a serpentine pattern, a square wave pattern, a spiral pattern, and a zig zag pattern and the second and/or third trace patterns may include a long rectangular shape.

With regards to the second trace pattern 1704, when drawing power therethrough to power the electronic measurement device 1714, a low resistance may be desired to draw enough power from the cell 104 to power the circuit of the electronic measurement device 1714. With regards to the first trace pattern 1702, the effective length and effective contact area may be larger relative to that of the other traces and this may force the resistance to be comparatively higher. With regards to the third trace pattern, current flow therethrough may not be desired to prevent the introduction of measurement errors. In an aspect, the area of a trace patterns discussed herein may be directly proportional to their relative resistances and the trace patterns may be disposed on at least one large wall surface 318 of the cell.

In further aspects, the first terminal may be a positive terminal and the second terminal may be a negative terminal and vice versa. As shown in FIG. 18, the electronic measurement device 1714 may be configured as an integrated control module such as an integrated BMS to provide a highly integrated battery pack design, with each electronic measurement device 1714 operable to measure the voltage of the respective cell, the temperature of the respective cell and to balance the respective cell. Each electronic measurement device 1714 may thus perform voltage measurement 1804, balance control 1802 and temperature measurement 1806 by electrically coupling the different trace patterns (conductive material 316) as needed to the terminals of the respective cell. In some cases, the electronic measurement device 1714 may also electrically couple the cells other external modules. On or more open spaces between the traces may be filled to maintain a uniform thickness trace patterns without the filler material contacting the traces in the case where the filler material is conductive.

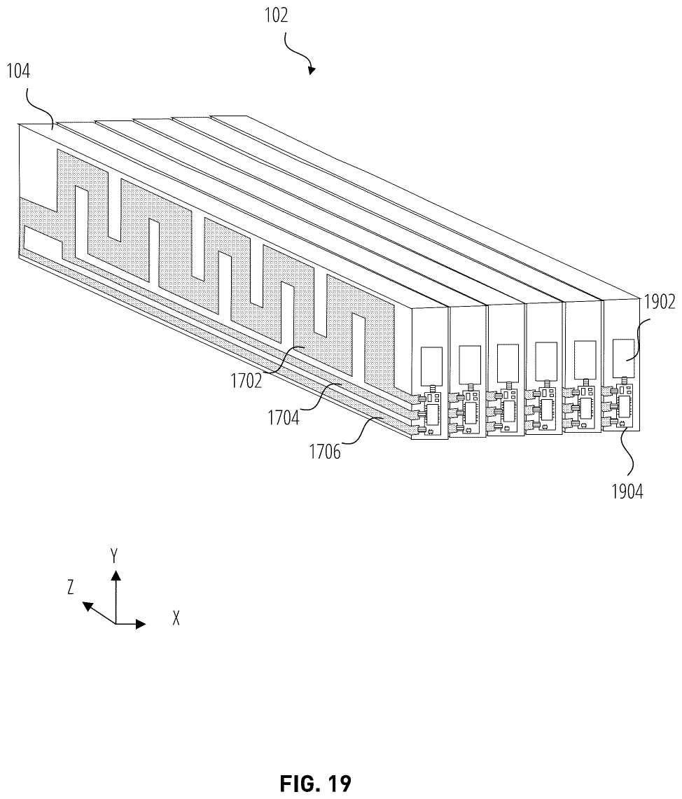

FIG. 19 illustrates a battery pack 102 or module comprising a plurality of the cells of FIG. 17. Such a battery pack may be incredibly useful for applications such as electric vehicle applications in which having individual control of cells of a plurality of cells may be beneficial. For example, each electronic measurement device 1714 may take measurements of its cell and communicate the measurements back to a central processor (central BMS) which may then issue commands back to the electronic measurement device 1714 to control activities of the cell such as balancing.

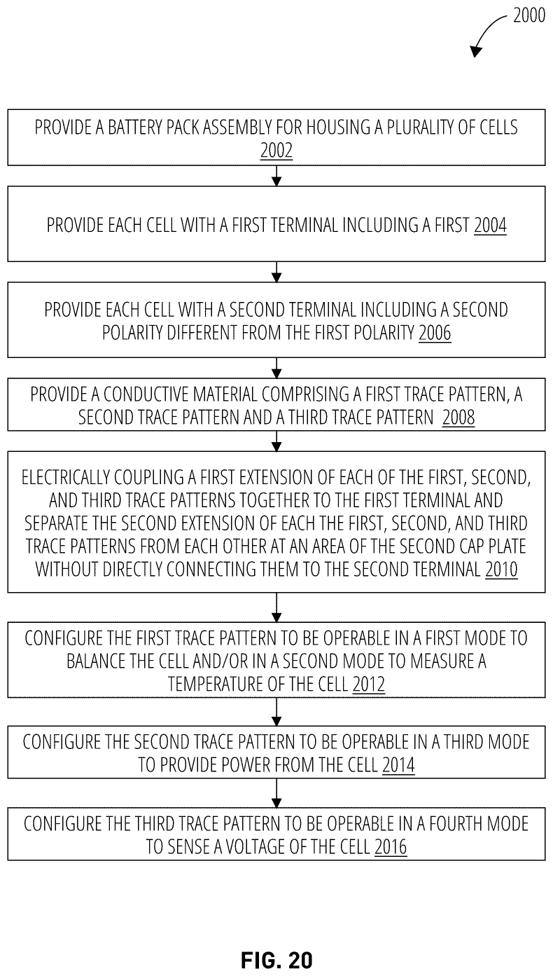

FIG. 20 depicts a flow chart of a routine 2000 for manufacturing a battery pack or a plurality of cells. The routine 2000 may be performed with the fabrication engine 2118 of FIG. 21.

In block 2002, fabrication engine 2118 provides a battery pack assembly for housing a plurality of cells wherein each cell comprises a housing extending along a first axis to define a width, a second axis orthogonal to the first axis to define a length, and a third axis orthogonal to the first and second axes to define a thickness. In block 2004, fabrication engine 2118 provides each cell with a first terminal 304 including a first polarity and disposes the first terminal 304 on a first cap plate of the cell. In block 2006, fabrication engine 2118 provides each cell with a second terminal 310 including a second polarity different from the first polarity and disposes the second terminal on a second cap plate which may alternatively be the same as the first cap plate, in which case the terminals may be separated by a distance. In block 2008, fabrication engine 2118 may provide a conductive material comprising a first trace pattern 1702, a second trace pattern 1704 and a third trace pattern 1706 which may be dimensioned for respective applications. The cell may comprise two or more of the trace patterns 1002, for example three trace patterns 1002. In block 2010, fabrication engine 2118 electrically coupling a first extension of each of the first, second, and third trace patterns together at the first terminal 304 at the first end and separate a second extension of each the first, second, and third trace patterns from each other on the second cap plate at the second end, the conductive material being disposed on at least one large wall surface of the cell and the at least one large wall surface being parallel to the YZ plane. In block 2012, fabrication engine 2118 configures the first trace pattern to be operable in a first mode to balance the cell and/or in a second mode to measure a temperature of the cell. In block 2014, fabrication engine 2118 configures the second trace pattern to be operable in a third mode to provide power from the cell. In block 2016, fabrication engine 2118 configures the third trace pattern to be operable in a fourth mode to sense a voltage of the cell. In an aspect, configuring the modes may be performed prior to electrically coupling them. Further, fabrication engine 2118 may separately electrically couple the second extension of each of the first trace pattern, second trace pattern, and third trace pattern to the electronic measurement device which may be integrated and disposed on the cell.

### Example Computer Platform

As discussed above, functions relating to methods and systems for fabricating a cell with an integrated conductive material can use of one or more computing devices connected for data communication via wireless or wired communication. FIG. 21 is a functional block diagram illustration of a computer hardware platform that can be used to control various aspects of a suitable computing environment in which the process discussed herein can be controlled. While a single computing device is illustrated for simplicity, it will be understood that a combination of additional computing devices, program modules, and/or combination of hardware and software can be used as well. The computer platform 2100 may include a central processing unit (CPU) 2104, a hard disk drive (HDD) 2106, random access memory (RAM) and/or read only memory (ROM) 2108, a keyboard 2110, a mouse 2112, a display 2114, and a communication interface 2116, which are connected to a system bus 2102.

In one embodiment, the hard disk drive (HDD) 2106, has capabilities that include storing a program that can execute various processes, such as the fabrication engine 2118, in a manner described herein. The fabrication engine 2118 may have various modules configured to perform distinct functions. For example, there may be a process module 2120 configured to control the different manufacturing processes discussed herein and others. There may be a conductive material integration control module 2122 operable to provide an appropriate dimensioning, bonding, and affixing of the conductive material 316 or traces to manufacture a highly integrated cell.

For the sake of brevity, conventional techniques related to making and using aspects of the disclosure may or may not be described in detail herein. In particular, various aspects of manufacturing and computing systems and specific programs to implement the various technical features described herein may be well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

1. A cell comprising:
a housing extending along a first axis to define a width, a second axis orthogonal to the first axis to define a length, and a third axis orthogonal to the first and second axes to define a thickness;
a first terminal with a first polarity, the first terminal being disposed on a first cap plate at a first end of the cell;
a second terminal with a second polarity different from the first polarity, the second terminal being disposed on a second cap plate at a second end of the cell;
a conductive material disposed on at least one large wall surface of the cell, and dimensioned to cover or substantially cover a whole area of the cell at the at least one large wall surface, the at least one large wall surface being parallel to the YZ plane, the conductive material further comprising:
a first extension at the first end of the cell, the first extension being electrically coupled to the first terminal; and
a second extension at the second end of the cell, the second extension being affixed to the second cap plate at the second end of the cell;
wherein the conductive material is dimensioned to provide a predetermined resistance for sensing a voltage of the cell.

2. The cell of claim 1, wherein the configuration of the conductive material enables electrical coupling of a first lead and a second lead of a voltage sensing device to the first and second terminals by electrical coupling of the first and second leads to the second extension and the second terminal at the second end of the cell respectively.

3. The cell of claim 1, wherein the second terminal is disposed on the second cap plate at the second end of the cell which is opposite the first end of the cell.

4. The cell of claim 1, wherein:
the second terminal is disposed on the second cap plate at the second end of the cell which is the same end as the first end of the cell; and
the first cap plate and the second cap plate are the same.

5. The cell of claim 1, further comprising:
an insulating film disposed between the conductive material and the housing; and
a cell wrap film configured to wrap an exposed periphery of the conductive material, the insulating film, and the housing into a wrapped cell.

6. The cell of claim 1, wherein:
the first terminal, the first extension, the second extension and the first lead have the first polarity; and
the second terminal and the second lead have the second polarity.

7. The cell of claim 1, wherein the cell is a large-format cell.

8. The cell of claim 7, wherein a length of the cell is about 400 mm.

9. The cell of claim 1, wherein a thickness of the conductive material is uniform or substantially uniform.

10. The cell of claim 1, wherein the conductive material comprises at least one of copper, aluminum, a conductive polymer, and another metal.

11. The cell of claim 1, wherein the housing comprises aluminum or steel.

12. The cell of claim 1, wherein the conductive material is disposed on one side of the cell.

13. A battery pack comprising:
a plurality of cells, each cell of the plurality of cells further comprising:
a housing extending along a first axis to define a width, a second axis orthogonal to the first axis to define a length, and a third axis orthogonal to the first and second axes to define a thickness;
a first terminal with a first polarity, the first terminal being disposed on a first cap plate at a first end of the cell;
a second terminal with a second polarity different from the first polarity, the second terminal being disposed on a second cap plate at a second end of the cell;
a conductive material disposed on at least one large wall surface of the cell, the at least one large wall surface being parallel to the YZ plane, and the conductive material further comprising:
a first extension at the first end of the cell, the first extension being electrically coupled to the first terminal; and
a second extension at the second end of the cell, the second extension being affixed to the second cap plate at the second end of the cell;
wherein the conductive material is dimensioned to provide a predetermined resistance for sensing a voltage of the cell.

14. The battery pack of claim 13, wherein:
the battery pack further comprises a voltage sensing device; and
for each cell of the plurality of cells, a first lead and a second lead of the voltage sensing device are electrically coupled to the first and second terminals by electrical coupling of the first and second leads to the second extension and the second terminal respectively.

15. The battery pack of claim 13, wherein the voltage sensing device is a battery management system.

16. A method comprising:
providing a battery pack comprising a plurality of cells, each cell of the plurality of cells further comprising a housing extending along a first axis to define a width, a second axis orthogonal to the first axis to define a length, and a third axis orthogonal to the first and second axes to define a thickness;
providing each cell with a first terminal including a first polarity and disposing the first terminal on a first cap plate at a first end of the cell;
providing each cell with a second terminal including a second polarity different from the first polarity and disposing the second terminal on a second cap plate at a second end of the cell;
dimensioning a conductive material, for each cell, to provide a predetermined resistance for sensing a voltage of the cell;
disposing the conductive material on at least one large wall surface of each cell, the at least one large wall surface being parallel to the YZ plane;
electrically coupling a first extension of the conductive material at the first end of each cell to the first terminal;
affixing a second extension of the conductive material at the second end of each cell to the second cap plate at the second end of the cell.

17-18. (canceled)

19. A cell comprising:
a housing extending along a first axis to define a width, a second axis orthogonal to the first axis to define a length, and a third axis orthogonal to the first and second axes to define a thickness;
a first terminal with a first polarity, the first terminal being disposed on a first cap plate at a first end of the cell;
a second terminal with a second polarity different from the first polarity, the second terminal being disposed on a second cap plate at a second end of the cell;
a conductive material comprising a trace pattern, the trace pattern disposed on at least one large wall surface of the cell and the trace pattern configured to optimize a net effective contact area and a uniform heat dissipation of the trace pattern, the at least one large wall surface being parallel to the YZ plane;
the trace pattern further comprising:
a first extension at the first end of the cell, the first extension being electrically coupled to the first terminal; and
a second extension at the second end of the cell, the second extension being affixed to the second cap plate at the second end of the cell.

20-43. (canceled)

44. A cell comprising:
a housing extending along a first axis to define a width, a second axis orthogonal to the first axis to define a length, and a third axis orthogonal to the first and second axes to define a thickness;
a first terminal with a first polarity, the first terminal being disposed on a first cap plate at a first end of the cell;
a second terminal with a second polarity different from the first polarity, the second terminal being disposed on a second cap plate at a second end of the cell;
a conductive material comprising a first trace pattern, a second trace pattern and a third trace pattern each having a first extension electrically coupled together at the first terminal at the first end and a second extension separated from each other on the second cap plate at the second end, the conductive material being disposed on at least one large wall surface of the cell and the at least one large wall surface being parallel to the YZ plane;
wherein the first trace pattern is operable in a first mode to balance the cell and/or in a second mode to measure a temperature of the cell,
wherein the second trace pattern is operable in a third mode to provide power from the cell, and
wherein the third trace pattern is operable in a fourth mode to sense a voltage of the cell.

45-66. (canceled)
